(19) United States
(12) Patent Application Publication
(10) Pub. No.: US 2022/0217294 A1
(43) Pub. Date: Jul. 7, 2022

(54) IMAGING DEVICE

(71) Applicant: Panasonic Intellectual Property Management Co., Ltd., Osaka (JP)

(72) Inventors: SANSHIRO SHISHIDO, Osaka (JP); YUUKO TOMEKAWA, Osaka (JP); SHINICHI MACHIDA, Osaka (JP); TAKANORI DOI, Osaka (JP)

(21) Appl. No.: 17/705,224

(22) Filed: Mar. 25, 2022

Related U.S. Application Data
(63) Continuation of application No. PCT/JP2020/036495, filed on Sep. 28, 2020.

(30) Foreign Application Priority Data
Oct. 30, 2019 (JP) 2019-197384

(51) Int. Cl. H04N 5/369; H04N 5/225; H04N 5/33

(52) U.S. Cl. CPC H04N 5/379; H04N 5/332; H04N 5/2254

(57) ABSTRACT

An imaging device includes: a first pixel array including a first photoelectric converter and first pixel electrodes connected to the first photoelectric converter; and a second pixel array including a second photoelectric converter and second pixel electrodes connected to the second photoelectric converter. The first pixel array and the second pixel array are stacked one on another. In a plan view, an area of an overlapping region defined by overlapping between the first pixel electrodes and a corresponding second pixel electrode of the second pixel electrodes is smaller than an area of a remaining region obtained by excluding the overlapping region from the corresponding second pixel electrode.

### BACKGROUND

### 1. Technical Field

The present disclosure relates to imaging devices.

### 2. Description of the Related Art

Imaging devices are widely used in various fields of products, such as video cameras, digital still cameras, surveillance cameras, and vehicle-mounted cameras. Examples of the imaging devices include charge-coupled device (CCD) imaging devices and complementary metal-oxide semiconductor (CMOS) imaging devices.

Nowadays, the sizes of pixels in each imaging device tend to be decreasing as the density of the pixels increases, and the area of a photoelectric converter including photodiodes or the like is also decreasing.

Japanese Patent No. 4320270 discloses an imaging device having stacked photoelectric conversion films. This type of imaging device may be called a stacked imaging device. The stacked imaging devices are advantageous in terms of increasing the density of the pixels.

### SUMMARY

In one general aspect, the techniques disclosed here feature an imaging device includes: a first pixel array including a first photoelectric converter and first pixel electrodes connected to the first photoelectric converter; and a second pixel array including a second photoelectric converter and second pixel electrodes connected to the second photoelectric converter. The first pixel array and the second pixel array are stacked one on another. In a plan view, an area of an overlapping region defined by overlapping between the first pixel electrodes and a corresponding second pixel electrode of the second pixel electrodes is smaller than an area of a remaining region obtained by excluding the overlapping region from the corresponding second pixel electrode.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a block diagram of an imaging apparatus according to a first embodiment of the present disclosure;

FIG. 2A is a sectional view of an imaging device illustrated in FIG. 1;

FIG. 2B is a diagram illustrating another positional relationship of a first pixel array and a second pixel array;

FIG. 2C is a sectional view of an imaging device according to a modification;

FIG. 3A is a view illustrating a positional relationship between a first pixel electrode and a second pixel electrode in each unit pixel when the imaging device is viewed in plan view;

FIG. 3B is a partially enlarged view of FIG. 3A;

FIG. 4A is a diagram illustrating another arrangement of the first pixel electrodes and the second pixel electrodes;

FIG. 4B is a diagram illustrating yet another arrangement of the first pixel electrodes and the second pixel electrodes;

FIG. 4C is a diagram illustrating still another arrangement of the first pixel electrodes and the second pixel electrodes;

FIG. 5A is a plan view of the first pixel electrodes and a first shield electrode;

FIG. 5B is a plan view of one second pixel electrode and a second shield electrode;

FIG. 5C is a plan view of the first pixel electrodes, the first shield electrode, the second pixel electrode, and the second shield electrode;

FIG. 6 is a plan view of the first pixel electrodes, the first shield electrode, the second pixel electrode, and the second shield electrode when the second pixel array is located at an upper layer, and the first pixel array is located at a lower layer;

FIG. 7 is a plan view illustrating a modification of the example described with reference to FIGS. 5A to 5C;

FIG. 8A is a plan view of the first pixel electrodes and the first shield electrode in another modification;

FIG. 8B is a plan view of one second pixel electrode and the second shield electrode in the other modification;

FIG. 8C is a plan view of the first pixel electrodes, the first shield electrode, the second pixel electrode, and the second shield electrode in the other modification;

FIG. 9A is a plan view of one second pixel electrode and the second shield electrode in a further modification;

FIG. 9B is a plan view of the first pixel electrodes, the first shield electrode, the second pixel electrode, and the second shield electrode in the further modification;

FIG. 10 is a plan view of the first pixel electrodes, the first shield electrode, the second pixel electrodes, and the second shield electrode in yet another modification;

FIG. 11A includes plan views each illustrating the first pixel electrodes, the first shield electrode, the second pixel electrodes, and the second shield electrode in still another modification;

FIG. 11B is a plan view of the second shield electrode constituted by linear portions that are separated from each other;

FIG. 12A is a plan view illustrating an arrangement of condensing lenses;

FIG. 12B is a plan view illustrating another arrangement of the condensing lenses;

FIG. 12C is a plan view illustrating yet another arrangement of the condensing lenses;

FIG. 13 is a sectional view of an imaging device according to a second embodiment of the present disclosure;

FIG. 14A is a schematic view illustrating a positional relationship of filters and the pixel electrodes;

FIG. 14B is a schematic view illustrating another positional relationship of the filters and the pixel electrodes;

FIG. 15A is a schematic view illustrating a positional relationship of the lenses and the pixel electrodes;

FIG. 15B is a schematic view illustrating another positional relationship of the lenses and the pixel electrodes;

FIG. 16 is a sectional view of an imaging device according to another embodiment;

FIG. 17 is a sectional view of an imaging device according to yet another embodiment; and

FIG. 18 is a block diagram illustrating a configuration of a camera system.

### DETAILED DESCRIPTION

### (Findings Underlying the Present Disclosure)

The present inventors have carried out intensive and extensive studies on reductions in sensitivity of stacked imaging devices. As a result, the present inventors have made the following findings.

When the density of pixels is increased in order to increase the resolution, the sensitivity of each pixel tends to decrease. In particular, in each stacked imaging device, capacitive coupling between electrodes provided in a photoelectric converter at an upper layer and electrodes provided in a photoelectric converter at a lower layer are likely to occur. A large coupling capacitance between the electrodes reduces a conversion gain in the imaging device, that is, sensitivity. When the coupling capacitance between the electrodes can be sufficiently reduced, it is possible to provide a stacked imaging device having high resolution and high sensitivity. Based on the findings described above, the present inventors have completed an imaging device in the present disclosure.

### Overview of One Aspect According to the Present Disclosure

An imaging device according to a first aspect of the present disclosure includes:

a first pixel array including a first photoelectric converter and first pixel electrodes connected to the first photoelectric converter; and

a second pixel array including a second photoelectric converter and second pixel electrodes connected to the second photoelectric converter.

The first pixel array and the second pixel array are stacked one on another.

In a plan view, an area of an overlapping region defined by overlapping between the first pixel electrodes and a corresponding second pixel electrode of the second pixel electrodes is smaller than an area of a remaining region obtained by excluding the overlapping region from the corresponding second pixel electrode.

According to the first aspect, it is possible to reduce a coupling capacitance between the first pixel electrode and the second pixel electrode. A reduction in the coupling capacitance suppresses or reduces a reduction in a conversion gain. In other words, the sensitivity of the imaging device improves.

In a second aspect of the present disclosure, for example, the imaging device according to the first aspect may further include:

a first filter that transmits light in a first wavelength range; and

a second filter that transmits light in a second wavelength range.

A center wavelength of the first wavelength range may differ from a center wavelength of the second wavelength range.

In the plan view, the second filter may overlap the corresponding second pixel electrode and does not necessarily have to overlap the first pixel electrodes.

According to the second aspect, it is possible to efficiently read out light in specific wavelengths as signals, while reducing the coupling capacitances between the first pixel electrode and the second pixel electrode. In addition, a uniform color filter array can be realized, yield improves, and color reproducibility also improves.

In a third aspect of the present disclosure, for example, the imaging device according to the first aspect may further include:

a first lens; and

a second lens.

In the plan view, an optical axis of the second lens may be located at a center region of the corresponding second pixel electrode and may deviate from a center region of each of the first pixel electrodes.

According to the third aspect, it is possible to efficiently read out light in specific wavelengths as signals, while reducing the coupling capacitances between the first pixel electrode and the second pixel electrode. A uniform lens array can be realized, yield improves, and also variations in incident angle characteristics are also suppressed or reduced.

In a fourth aspect of the present disclosure, for example, in the imaging device according to the first aspect, in the plan view, the first pixel electrodes and the second pixel electrodes do not necessarily have to overlap each other, and the area of the overlapping region may be zero. This configuration is advantageous in further reducing the coupling capacitance between the electrodes.

In a fifth aspect of the present disclosure, for example, the imaging device according to the second aspect may further include a third filter that transmits light in a third wavelength range different from the first wavelength range and the second wavelength range; and in the plan view, the third filter may overlap a first pixel electrode that is included in the first pixel electrodes and that does not overlap the first filter. According to this configuration, it is possible to read out light in three different wavelength ranges as signals, while reducing the coupling capacitance between the pixel electrodes.

In a sixth aspect of the present disclosure, for example, the imaging device according to the third aspect may further include a third lens; and in the plan view, an optical axis of the third lens may be located at a center region of a first pixel electrode that is included in the first pixel electrodes, and the optical axis of the first lens is not located at the center region of the first pixel electrode. According to this configuration, it is possible to efficiently read out light in three mutually different wavelength ranges as signals, while reducing the coupling capacitance between the pixel electrodes.

In a seventh aspect of the present disclosure, for example, in the imaging device according to the sixth aspect, an optical axis of the second lens may deviate from a center region of each of the first pixel electrodes. According to this configuration, it is possible to efficiently read out light in three mutually different wavelength ranges as signals, while reducing the coupling capacitance between the pixel electrodes.

In an eighth aspect of the present disclosure, for example, in the imaging device according to one of the second to seventh aspects, the first pixel array may be arranged closer to a light-receiving surface of the imaging device than the second pixel array, and a wavelength of the light in the second wavelength range may be longer than a wavelength of the light in the first wavelength range. According to this configuration, images based on light in a first wavelength range can be formed with high sensitivity.

In a ninth aspect of the present disclosure, for example, in the imaging device according to one of the second to seventh aspects, the second pixel array may be arranged closer to a light-receiving surface of the imaging device than the first pixel array, and a wavelength of the light in the second wavelength range may be longer than a wavelength of the light in the first wavelength range. This configuration is advantageous in terms of reducing influences of crosstalk and the parasitic capacitance.

In a tenth aspect of the present disclosure, for example, in the imaging device according to the first aspect, each of the first pixel electrodes may include indium tin oxide (ITO). When the first pixel electrodes are made of material including ITO, light in the second wavelength range is transmitted through the first pixel electrodes and is absorbed by the second photoelectric converter.

In an 11th aspect of the present disclosure, for example, in the imaging device according to one of the second to tenth aspects, the first wavelength range may include a wavelength range of visible light. Clear images are acquired based on visible light.

In a 12th aspect of the present disclosure, for example, in the imaging device according to one of the second to 11th aspects, the second wavelength range may include a wavelength range of near infrared light. Highly useful images are acquired based on near infrared light.

In a 13th aspect of the present disclosure, for example, the imaging device according to the first aspect may further include: a substrate that supports the first pixel array and the second pixel array; first plugs; and second plugs. Each of the first plugs connects a corresponding one of the first pixel electrodes and the substrate. Each of the second plugs connects a corresponding one of the second pixel electrodes and the substrate. In the plan view, each of the first plugs does not necessarily have to overlap the second pixel electrodes, and each of the second plugs does not necessarily have to overlap the first pixel electrodes. This configuration also contributes to improving the sensitivity.

Embodiments of the present disclosure will be described below with reference to the accompanying drawings. The present disclosure is not limited to the embodiments described below.

### First Embodiment

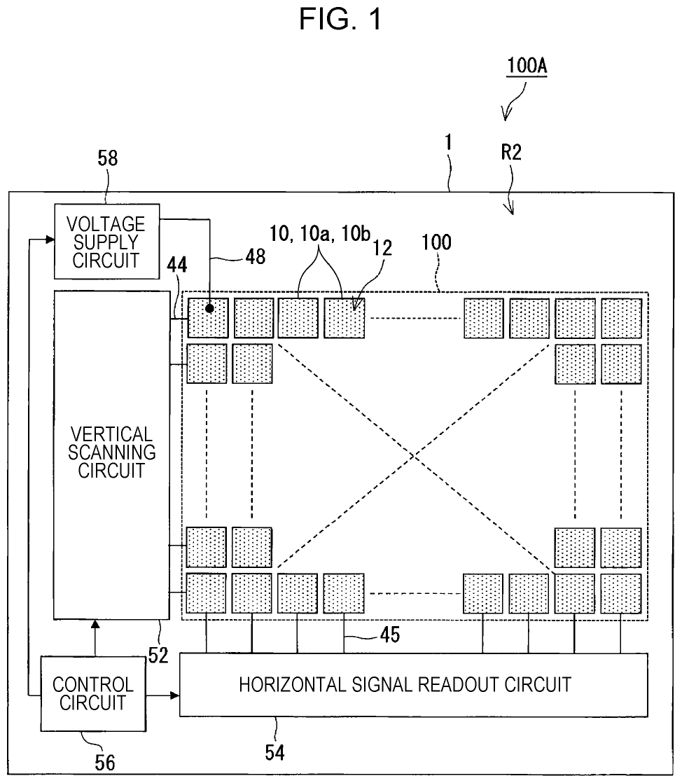

FIG. 1 illustrates a configuration of an imaging apparatus 100A according to a first embodiment of the present disclosure. The imaging apparatus 100A includes an imaging device 100. The imaging device 100 includes a semiconductor substrate 1 and a plurality of unit pixels 10. The plurality of unit pixels 10 is provided at an upper side of the semiconductor substrate 1. The unit pixels 10 are supported by the semiconductor substrate 1. The unit pixels 10 may be partly constituted by the semiconductor substrate 1.

Each unit pixel 10 includes at least one first pixel 10a and at least one second pixel 10b. Each first pixel 10a is a pixel for generating data based on light in a first wavelength range. Each second pixel 10b is a pixel for generating data based on light in a second wavelength range. The second wavelength range is a wavelength range having a center wavelength different from a center wavelength of the first wavelength range. The wavelength of light in the second wavelength range is, for example, longer than the wavelength of light in the first wavelength range. The first wavelength range is, for example, the wavelength range of visible light. The second wavelength range is, for example, the wavelength range of near infrared light. Data to be generated is typically image data. Clear images are acquired based on visible light. The images may be full-color images or may be monochrome images. Highly useful images are acquired based on near infrared light.

In the present embodiment, each unit pixel 10 includes four first pixels 10a and one second pixel 10b. In the unit pixel 10, however, the number of first pixels 10a and the number of second pixels 10b are not particularly limited. In the unit pixel 10, the ratio (N1/N2) of the number N1 of first pixels 10a to the number N2 of second pixels 10b may be 4 to 1, 2 to 1, or 1 to 1. Herein, the number of pixels is equal to the number of pixel electrodes.

The semiconductor substrate 1 may be a circuit substrate including various electronic circuits. The semiconductor substrate 1 is implemented by, for example, a silicon (Si) substrate.

The unit pixels 10 includes a photoelectric converter 12. Upon receiving incident light, the photoelectric converter 12 generates positive charge and negative charge, typically, hole-electron pairs. The photoelectric converter 12 includes at least one photoelectric conversion layer arranged at the upper side of the semiconductor substrate 1. In FIG. 1, the photoelectric converter 12 in the unit pixels 10 is illustrated as being spatially separated portions. This, however, is for merely convenience of description. The photoelectric converter 12 in the unit pixels 10 can be continuously arranged at the upper side of the semiconductor substrate 1, without gaps being interposed therein.

In FIG. 1, the unit pixels 10 are arrayed in a plurality of rows by a plurality of columns, that is, m rows by n columns, where m and n individually represent integers greater than or equal to 1. The unit pixels 10 are, for example, two-dimensionally arrayed at the semiconductor substrate 1 to form an imaging region. When the imaging apparatus 100A is viewed in plan view, the imaging device 100 can be defined as a region having at least one photoelectric conversion layer.

The number of unit pixels 10 and the arrangement thereof are not particularly limited. In FIG. 1, the center of each unit pixel 10 is located at a grid point of a square grid. The unit pixels 10 may be arranged so that the center of each unit pixel 10 is located at a grid point of a triangular grid, a hexagonal grid, or the like. When the unit pixels 10 are arrayed one-dimensionally, the imaging device 100 can be used as a line sensor.

The imaging apparatus 100A has peripheral circuitry formed at the semiconductor substrate 1.

The peripheral circuitry includes a vertical scanning circuit 52 and a horizontal signal readout circuit 54. The peripheral circuitry can additionally include a control circuit 56 and a voltage supply circuit 58. The peripheral circuitry may further include a signal processing circuit, an output circuit, and so on. These circuits are provided at the semiconductor substrate 1. Part of the peripheral circuitry may be arranged at another substrate different from the semiconductor substrate 1 at which the unit pixels 10 are formed.

The vertical scanning circuit 52 is also referred to as a “row scanning circuit”. Address signal lines 44 are provided corresponding to the respective rows of the unit pixels 10 and are connected to the vertical scanning circuit 52. Signal lines provided corresponding to the rows of the unit pixels 10 are not limited to the address signal lines 44, and a plurality of types of signal line provided for each of the rows of the unit pixels 10 can be connected to the vertical scanning circuit 52. The horizontal signal readout circuit 54 is also called a column scanning circuit. Vertical signal lines 45 are provided corresponding to the respective columns of the unit pixels 10 and are connected to the horizontal signal readout circuit 54.

The control circuit 56 receives command data, a clock signal, and so on given from outside of the imaging apparatus 100A and controls the entire imaging apparatus 100A. Typically, the control circuit 56 has a timing generator and supplies drive signals to the vertical scanning circuit 52, the horizontal signal readout circuit 54, the voltage supply circuit 58, and so on. The control circuit 56 can be implemented by, for example, a microcontroller including one or more processors. Functions of the control circuit 56 may be realized by a combination of a general-purpose processing circuit and software or may be realized by hardware dedicated to processing as described above.

The voltage supply circuit 58 supplies a predetermined voltage to the unit pixels 10 through a voltage line 48. The voltage supply circuit 58 is not limited to a particular power supply circuit. The voltage supply circuit 58 may be a circuit that converts a voltage, supplied from a power source such as a battery, into the predetermined voltage or may be a circuit that generates the predetermined voltage. The voltage supply circuit 58 may be a portion of the vertical scanning circuit 52. Those circuits included in the peripheral circuitry can be arranged in a peripheral region R2 outside the imaging device 100.

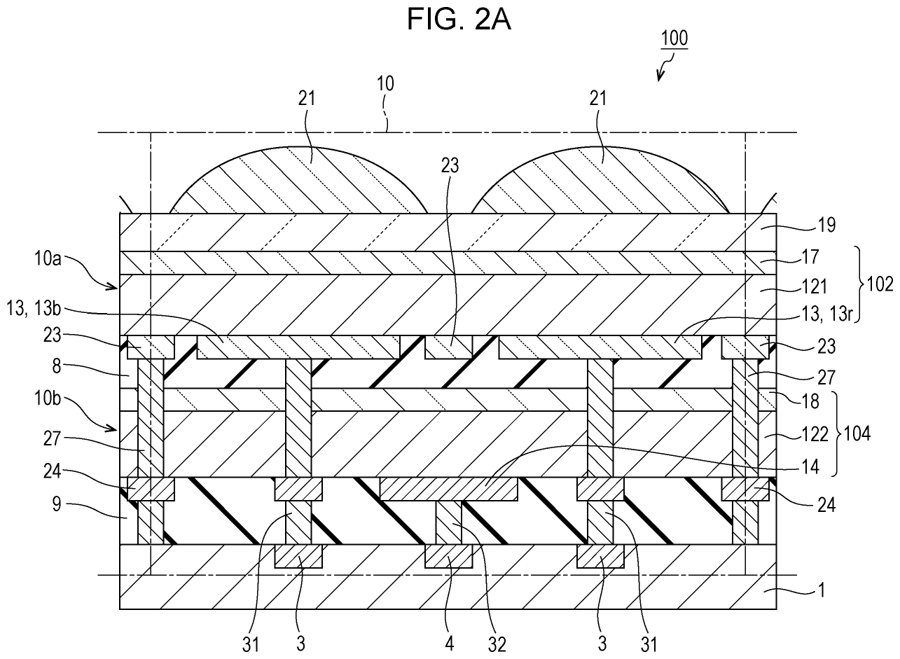

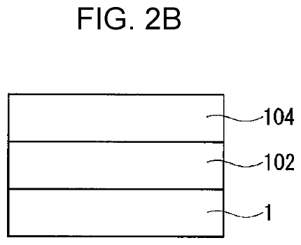

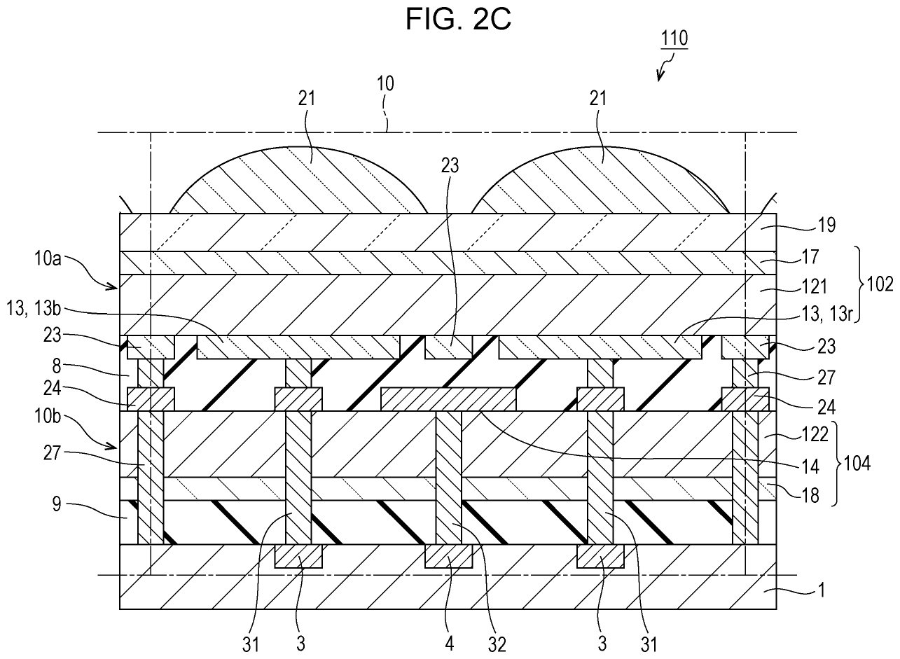

FIGS. 2A, 2B, and 2C each illustrate a cross section of the imaging device 100.

The imaging device 100 has a first pixel array 102 and a second pixel array 104. The first pixel array 102 and the second pixel array 104 are supported by the semiconductor substrate 1. The second pixel array 104 is arranged between the semiconductor substrate 1 and the first pixel array 102. The first pixel array 102 is stacked at an upper side of the second pixel array 104. In the present embodiment, an insulating layer 8 is provided between the first pixel array 102 and the second pixel array 104. An insulating layer 9 is provided between the semiconductor substrate 1 and the second pixel array 104. The first pixel array 102 and the second pixel array 104 may be in contact with each other. The “upper” and “lower” directions as used herein are defined with reference to the semiconductor substrate 1. The direction away from the semiconductor substrate 1 is the upper direction. The direction toward the semiconductor substrate 1 is the lower direction.

The first pixel array 102 includes a first photoelectric conversion layer 121, a first counter electrode 17, and a plurality of first pixel electrodes 13. The first photoelectric conversion layer 121, the first counter electrode 17, and the first pixel electrodes 13 constitute the first pixels 10a. The first photoelectric conversion layer 121 may be a single layer shared by two or more first pixels 10a. In the imaging device 100, the first pixel electrodes 13 are arrayed in a grid pattern. FIG. 2A illustrates two adjacent first pixel electrodes 13.

The second pixel array 104 includes a second photoelectric conversion layer 122, a second counter electrode 18, and a plurality of second pixel electrodes 14. The second photoelectric conversion layer 122, the second counter electrode 18, and the second pixel electrodes 14 constitute the second pixels 10b. The second photoelectric conversion layer 122 is a single layer shared by two or more second pixels 10b. In the imaging device 100, the second pixel electrodes 14 are arrayed in a grid pattern. FIG. 2A illustrates only one second pixel electrode 14.

The first photoelectric conversion layer 121 and the second photoelectric conversion layer 122 correspond to the photoelectric converter 12 described above with reference to FIG. 1. The first photoelectric conversion layer 121 corresponds to a first photoelectric converter, and the second photoelectric conversion layer 122 corresponds to a second photoelectric converter. The first photoelectric conversion layer 121 and the second photoelectric conversion layer 122 are each made of photoelectric conversion material. The photoelectric conversion material is typically organic material.

The first photoelectric conversion layer 121 absorbs light in the first wavelength range to generate charge. The second photoelectric conversion layer 122 absorbs light in the second wavelength range to generate charge. The center wavelength of the first wavelength range differs from the center wavelength of the second wavelength range. The wavelength of light in the second wavelength range is longer than the wavelength of light in the first wavelength range. The first wavelength range is, for example, the wavelength range of visible light. The first photoelectric conversion layer 121 is made of material having sensitivity to visible light. The second wavelength range is, for example, the wavelength range of near infrared light. The second photoelectric conversion layer 122 is made of material having sensitivity to near infrared light. The two photoelectric conversion layers having characteristics different from each other provide two types of data having different properties.

In the present embodiment, the first photoelectric conversion layer 121, the second photoelectric conversion layer 122, and the semiconductor substrate 1 are arranged in that order. In a normal direction of the semiconductor substrate 1, the second photoelectric conversion layer 122 is arranged between the first photoelectric conversion layer 121 and the semiconductor substrate 1. In other words, the first pixel array 102 is arranged closer to a light-receiving surface of the imaging device 100 than the second pixel array 104.

When the first photoelectric conversion layer 121 is located relatively close to the light-receiving surface, no light is absorbed by the second photoelectric conversion layer 122, and thus full-color images can be formed with high sensitivity. Meanwhile, in many cases, resolution and sensitivity that are as high as those for full-color images are not required for images based on near infrared light. Also, since vias for passing plugs do not have to be formed in the first photoelectric conversion layer 121, damage due to processing, such as etching, is less likely to remain in the first photoelectric conversion layer 121. This reduces the amount of noise, thus leading to enhancing the sensitivity of the first photoelectric conversion layer 121. In one example of the imaging device 100, the number of first pixel electrodes 13 is larger than the number of second pixel electrodes 14. Thus, when the first pixel array 102 forms an image based on visible light, a high-sensitivity and high-resolution image that suits human vision is formed. The second pixel array 104 forms an image based on near infrared light. Even when the effective sensitivity of the second pixel array 104 is low, a large light-receiving surface is ensured for the second pixel electrode 14, thus achieving sufficient sensitivity. From such a point of view, the arrangement in the present embodiment is advantageous.

The “plugs” as used herein refers to conductors that extend in the normal direction of the semiconductor substrate 1 to provide electrical connection between layers or between a layer and the semiconductor substrate 1. The “vias” are holes that are disposed through a layer in a thickness direction. Conductors disposed in holes may also be referred to as “vias”.

In the imaging device 100, the arrangement order of the first photoelectric conversion layer 121 and the second photoelectric conversion layer 122 is not particularly limited.

FIG. 2B illustrates another positional relationship between the first pixel array 102 and the second pixel array 104. In this example, the first pixel array 102 is arranged between the second pixel array 104 and the semiconductor substrate 1. That is, the first photoelectric conversion layer 121 is arranged between the second photoelectric conversion layer 122 and the semiconductor substrate 1. The second pixel array 104 is arranged closer to the light-receiving surface than the first pixel array 102.

For example, when the second photoelectric conversion layer 122 is made of material having sensitivity to near infrared light, and the material is highly transmissive to visible light, a problem of sensitivity decline is less likely to occur even when the first photoelectric conversion layer 121 for generating charge resulting from visible light is located at a lower layer. Also, since RGB signals are needed in order to form a full-color image, a larger number of electrodes and a larger number of plugs are connected to the first photoelectric conversion layer 121. The shorter the plugs, the more advantageous in terms of reducing influences of crosstalk and parasitic capacitance. Thus, it is advantageous that the first photoelectric conversion layer 121 be located at a lower layer, in terms of the lengths of the plugs. Since the number of second pixel electrodes 14 included in the second pixel array 104 is smaller than the number of first pixel electrodes 13 included in the first pixel array 102, the number of second plugs 32 disposed through the first photoelectric conversion layer 121 is also small when the second pixel array 104 is located at an upper layer. Since the number of vias to be formed in the first photoelectric conversion layer 121 can be reduced, damage due to processing, such as etching, is less likely to remain in the first photoelectric conversion layer 121.

The first pixel electrodes 13 are electrically connected to the first photoelectric conversion layer 121. The first pixel electrodes 13 collect charge (holes or electrons) resulting from light in the first wavelength range. The second pixel electrodes 14 are electrically connected to the second photoelectric conversion layer 122. The second pixel electrodes 14 collect charge (holes or electrons) resulting from light in the second wavelength range.

Each first pixel electrode 13 is a transparent electrode that is transmissive to visible light and/or near infrared light. The transparent electrode is made of transparent conductive oxide, such as indium tin oxide (ITO). Each second pixel electrodes 14 is a non-transparent electrode that is not transmissive to visible light and/or near infrared light. Examples of material of the non-transparent electrode include metal, metal oxide, metal nitride, and electrically conductive polysilicon. When the first pixel electrodes 13 are made of material including ITO, light in the second wavelength range is transmitted through the first pixel electrodes 13 and is absorbed by the second photoelectric conversion layer 122. This makes it possible to ensure sufficient high sensitivity for the second pixels 10b.

Herein, “being transmissive” means that the transmittance of light in a particular wavelength range is 40% or more. The wavelength range of visible light is, for example, 400 to 780 nm. The wavelength range of near infrared light is, for example, 780 to 2000 nm. The transmittance can be calculated using a method specified by Japanese Industrial Standard (JIS) R3106 (1998).

The insulating layers 8 and 9 are made of insulating material, such as silicon dioxide (SiO₂). Specifically, the insulating layer 8 is provided between the first pixel electrodes 13 and the second counter electrode 18. Specifically, the insulating layer 9 is provided between the second pixel electrodes 14 and the semiconductor substrate 1.

The first counter electrode 17 is electrically connected to the first photoelectric conversion layer 121. The first counter electrode 17 is shared by two or more first pixels 10a. The second counter electrode 18 is electrically connected to the second photoelectric conversion layer 122. The second counter electrode 18 is shared by two or more second pixels 10b. Each of the first counter electrode 17 and the second counter electrode 18 is a transparent electrode that is transmissive to visible light and/or near infrared light.

The first counter electrode 17 is provided corresponding to the first pixel electrodes 13. The first photoelectric conversion layer 121 is sandwiched between the first counter electrode 17 and the first pixel electrodes 13. The second counter electrode 18 is provided corresponding to the second pixel electrodes 14. The second photoelectric conversion layer 122 is sandwiched between the second counter electrode 18 and the second pixel electrodes 14.

The positional relationship between the first pixel electrodes 13 and the first counter electrode 17 may be interchanged. In such a case, it is possible to integrate the first counter electrode 17 and the second counter electrode 18 together by omitting the insulating layer 8. In other words, a single counter electrode that is in electrical contact with both the first photoelectric conversion layer 121 and the second photoelectric conversion layer 122 may be provided therebetween.

Each unit pixel 10 further includes at least one first plug 31 and at least one second plug 32. In the present embodiment, each unit pixel 10 includes four first plugs 31 and one second plug 32. The first plugs 31 and the second plug 32 extend in the normal direction of the semiconductor substrate 1. The first plugs 31 provide electrical connection between the semiconductor substrate 1 and the corresponding first pixel electrodes 13. The second plug 32 provides electrical connection between the semiconductor substrate 1 and the second pixel electrode 14.

The first plugs 31 and the second plug 32 are made of electrically conductive material. Examples of the electrically conductive material include metal, metal oxide, metal nitride, and electrically conductive polysilicon.

The semiconductor substrate 1 has first charge accumulation regions 3 and second charge accumulation regions 4. The first charge accumulation regions 3 and the second charge accumulation regions 4 may be portions of the unit pixels 10. The first charge accumulation regions 3 and the second charge accumulation regions 4 are n-type or p-type impurity regions. The first plugs 31 provide electrical connection between the first charge accumulation regions 3 and the first pixel electrodes 13. The second plug 32 provides electrical connection between the second charge accumulation region 4 and the second pixel electrode 14.

The semiconductor substrate 1 may have a plurality of transistors for reading out and resetting charge accumulated in the first charge accumulation regions 3 and the second charge accumulation regions 4.

When the imaging device 100 is illuminated with light, electron-hole pairs are generated in the first photoelectric conversion layer 121 and the second photoelectric conversion layer 122.

For example, when a voltage is applied between the first counter electrode 17 and the first pixel electrode 13 so that a potential of the first counter electrode 17 exceeds a potential of the first pixel electrode 13, holes, which are positive charge, are gathered at the first pixel electrode 13, and electrons, which are negative charge, are gathered at the first counter electrode 17. The holes gathered at the first pixel electrode 13 are accumulated in the first plug 31 and the first charge accumulation region 3.

When a voltage is applied between the second counter electrode 18 and the second pixel electrode 14 so that a potential of the second counter electrode 18 exceeds a potential of the second pixel electrode 14, holes, which are positive charge, are gathered at the second pixel electrode 14, and electrons, which are negative charge, are gathered at the second counter electrode 18. The holes that are gathered at the second pixel electrode 14 are accumulated in the second plug 32 and the second charge accumulation region 4.

A blocking layer that blocks flowing of charge into the pixel electrodes during dark time may be provided between the pixel electrodes and the photoelectric conversion layer.

The imaging device 100 in the present embodiment has a multi-layer structure. The “multi-layer” means that a plurality of photoelectric conversion layers lies in the normal direction of the semiconductor substrate 1. Since the multi-layer structure makes it possible to ensure a sufficient area for the pixel electrodes, it is advantageous in enhancing the sensitivity of the pixels. Since two photoelectric conversion layers, that is, the first photoelectric conversion layer 121 and the second photoelectric conversion layer 122, are provided in the present embodiment, it can be said that the imaging device 100 has a two-layer structure. The first photoelectric conversion layer 121 and the second photoelectric conversion layer 122 typically have photoelectric conversion characteristics that are different from each other.

In general, a band gap of material having sensitivity to near infrared light is narrower than a band gap of material (panchromatic material) having sensitivity to visible light. Thus, when a photoelectric conversion layer is formed using material having sensitivity to near infrared light, the amount of dark current due to thermal excitation at ordinary temperature increases in principle. In the present embodiment, since the first photoelectric conversion layer 121 and the second photoelectric conversion layer 122 are electrically insulated from each other, it is possible to prevent dark current generated in the second photoelectric conversion layer 122 from flowing into the first photoelectric conversion layer 121. As a result, it is possible to prevent image quality deterioration due to dark current.

The imaging device 100 further includes a color filter 19. The color filter 19 is arranged at an upper side of the first photoelectric conversion layer 121. The first photoelectric conversion layer 121 is illuminated with light transmitted through the color filter 19. The color filter 19 is, for example, a Bayer filter. Owing to functions of the color filter 19, information on blue, green, and red can be obtained from the first photoelectric conversion layer 121 to form a full-color image. When the color filter 19 is not provided, the imaging device 100 can form a monochrome image.

The imaging device 100 further includes a plurality of condensing lenses 21. The condensing lenses 21 are arranged at the upper side of the semiconductor substrate 1 so as to form the light-receiving surface of the imaging device 100. The condensing lenses 21 are arranged at an upper side of the first pixel electrodes 13 in a one-on-one correspondence relationship. According to the condensing lens 21, the amount of light that is obliquely incident can be reduced. This makes it possible to suppress or reduce color mixing caused by oblique incidence.

The imaging device 100 further includes a first shield electrode 23 and a second shield electrode 24. The first shield electrode 23 is provided between the adjacent first pixel electrodes 13. The first shield electrode 23 is located at the same level as the first pixel electrodes 13. The second shield electrode 24 is provided between the adjacent second pixel electrodes 14. The second shield electrode 24 is located at the same level as the second pixel electrodes 14. The “same level” means that being located in the same layer, in other words, being located at equal distances from the semiconductor substrate 1. The first shield electrode 23 and the second shield electrode 24 are in electrical contact with the first photoelectric conversion layer 121 and the second photoelectric conversion layer 122, respectively.

Provision of the first shield electrode 23 and the second shield electrode 24 improves charge collection efficiency of each of the respective first pixel electrodes 13 and second pixel electrodes 14. That is, applying an appropriate bias voltage to the first shield electrode 23 provided between one first pixel electrode 13 and another first pixel electrode 13 causes an appropriate potential gradient to occur in the first photoelectric conversion layer 121. This potential gradient improves the charge collection efficiency and also suppresses or reduces inflow of charge from the adjacent first pixel 10a and outflow of charge to the adjacent first pixel 10a. As a result, electrical color mixing is prevented. Similarly, applying an appropriate bias voltage to the second shield electrode 24 provided between one second pixel electrode 14 and another second pixel electrode 14 causes an appropriate potential gradient to occur in the second photoelectric conversion layer 122. This potential gradient improves the charge collection efficiency and also suppresses or reduces inflow of charge from the adjacent second pixel 10b and outflow of charge to the adjacent second pixel 10b. As a result, electrical color mixing is prevented. Accordingly, it is possible to realize both high resolution and high sensitivity.

The first shield electrode 23 is a transparent electrode that is transmissive to visible light and/or near infrared light. The transparent electrode is made of transparent conductive oxide, such as ITO. The second shield electrode 24 is a non-transparent electrode that is not transmissive to visible light and/or near infrared light. Examples of material of the non-transparent electrode include metal, metal oxide, metal nitride, and electrically conductive polysilicon. The first shield electrode 23 may be made of material that is the same as or different from the material of the first pixel electrodes 13. The second shield electrode 24 may be made of material that is the same as or different from the material of the second pixel electrodes 14.

In the present embodiment, the first shield electrode 23 is a single electrode having a single potential. The second shield electrode 24 is a single electrode having a single potential. The first shield electrode 23, however, may have portions that are insulated from each other. The portions of the first shield electrode 23 may have the same potential or may have potentials that are different from each other. The second shield electrode 24 may have portions that are insulated from each other. The portions of the second shield electrode 24 may have the same potential or may have potentials that are different from each other.

The imaging device 100 further includes at least one plug 27 electrically connected to the first shield electrode 23 and the second shield electrode 24. The at least one plug 27 is made of electrically conductive material, such as metal, metal oxide, metal nitride, or electrically conductive polysilicon. When the first shield electrode 23 is electrically continuous with the second shield electrode 24, and a voltage is applied to one of the first shield electrode 23 and the second shield electrode 24, the same voltage is also applied to the other of the first shield electrode 23 and the second shield electrode 24. That is, voltage application and control thereof are easy.

FIG. 2C illustrates a cross section of an imaging device 110 according to a modification. In the imaging device 110, the first pixel electrodes 13 are in contact with an upper surface of the insulating layer 8, and the second pixel electrodes 14 are in contact with a lower surface of the insulating layer 8. That is, the first pixel electrodes 13 and the second pixel electrodes 14 are adjacent to each other, with the insulating layer 8 being interposed therebetween. The first pixel array 102 and the second pixel array 104 are stacked so that the first pixel electrodes 13 and the second counter electrode 18 face each other with the insulating layer 8 being interposed therebetween.

Next, a positional relationship between the first pixel electrodes 13 and the second pixel electrodes 14 will be described in detail.

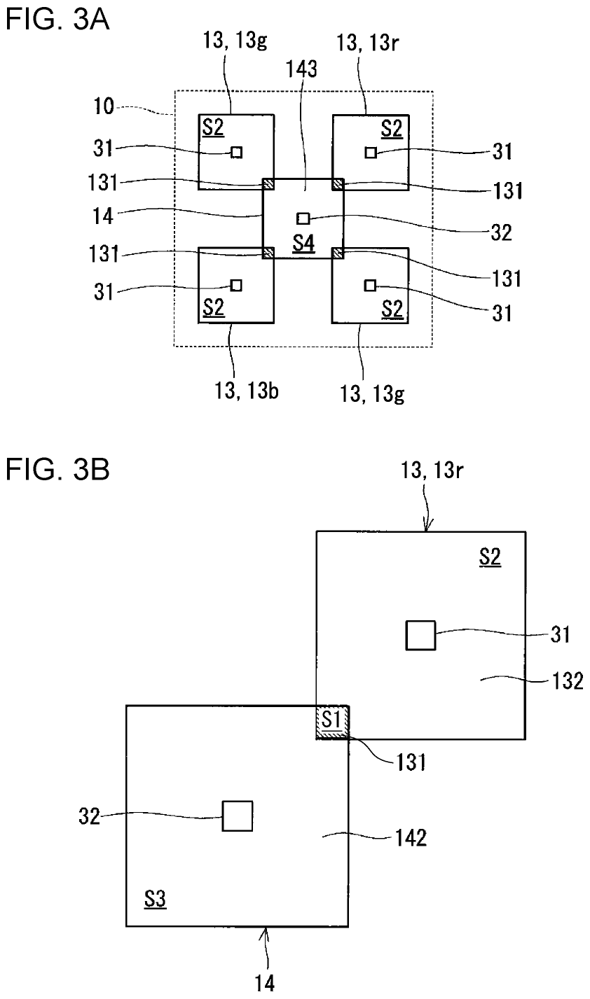

FIG. 3A illustrates a positional relationship between the first pixel electrodes 13 and the second pixel electrode 14 in each unit pixel 10 when the imaging device 100 is viewed in plan view. Each unit pixel 10 includes four first pixel electrodes 13 and one second pixel electrode 14. In accordance with a Bayer arrangement, the four first pixel electrodes 13 include a first pixel electrode 13r for collecting charge resulting from red light, two first pixel electrodes 13g for collecting charge resulting from green light, and a first pixel electrode 13b for collecting charge resulting from blue light. In plan view, the first pixel electrodes 13 overlap the second pixel electrode 14. The position of the barycenter of each first pixel electrode 13 differs from the position of the barycenter of the second pixel electrode 14. A center region of each first pixel electrode 13 and a center region of the second pixel electrode 14 are offset in an in-plane direction. A part of each first pixel electrode 13 overlaps a part of the second pixel electrode 14. In the present embodiment, each first pixel electrode 13 overlaps the second pixel electrode 14. Each second pixel electrode 14 is arranged at a corresponding intersection of a plurality of intersections in the Bayer arrangement.

FIG. 3B is a partially enlarged view of FIG. 3A. An area S1 of an overlapping region 131 defined by overlapping between each of the first pixel electrodes 13 and the second pixel electrode 14 is smaller than an area S2 of a remaining region 132 obtained by excluding the overlapping region 131 from the first pixel electrode 13. According to this configuration, it is possible to reduce a coupling capacitance between each first pixel electrode 13 and the second pixel electrode 14. A reduction in the coupling capacitance suppresses or reduces a reduction in a conversion gain. In other words, the sensitivity of the imaging device 100 improves. In one example, the ratio (S1/(S1+S2)) of the area S1 of each overlapping region 131 to the area (S1+S2) of the first pixel electrode 13 is smaller than 1 to 2 or may be smaller than 1 to 4.

As illustrated in FIG. 3B, the area S1 of the overlapping region 131 is smaller than an area S3 of a remaining region 142 obtained by excluding the overlapping region 131 from the second pixel electrode 14. This configuration also contributes to reducing the coupling capacitance between the electrodes.

The shape of the first pixel electrode 13 is, for example, rectangle and may be square in plan view. The shape of the second pixel electrode 14 is, for example, rectangle and may be square in plan view. The first plug 31 is located at the center region of the first pixel electrode 13. The second plug 32 is located at the center region of the second pixel electrode 14. Since the overlapping region 131 is small, the degree of freedom of the arrangement of the first plug 31 and the second plug 32 is high. In plan view, the first plug 31 is located outside the range of the second pixel electrode 14, and the second plug 32 is located outside the range of the first pixel electrode 13. Since the distances from the first plug 31 to the second pixel electrode 14 and the second plug 32 in plan view are sufficiently large, the coupling capacitance between the first pixel electrode 13 and the second pixel electrode 14 via the first plug 31 is sufficiently small. Crosstalk between the first plug 31 and the second plug 32 is also suppressed or reduced. These also contribute to improving the sensitivity of the imaging device 100.

It is not essential that the plug be arranged at the center region of each corresponding pixel electrode. The position of each plug can be changed, as appropriate.

Herein, the “center region of each pixel electrode” refers to a region having a certain area including the barycenter of the pixel electrode when the pixel electrode is viewed in plan view. Specifically, when each pixel electrode has a generally rectangular shape in plan view, the pixel electrode is divided into nine rectangular regions so that the areas of the respective divided regions are equal to each other. Of the nine rectangular regions, the region including the barycenter of the pixel electrode is the center region. When the pixel electrode has a notch or the like, a smallest quadrangular shape surrounding the pixel electrode may be divided into nine regions. The barycenter of the pixel electrode may be the barycenter of the smallest quadrangular shape surrounding the pixel electrode. A region other than the center region is an outer periphery region.

In the example illustrated in FIG. 3A, each of the first pixel electrodes 13 overlaps the second pixel electrode 14. An area S4 of a remaining region 143 obtained by excluding all the overlapping regions 131 from the second pixel electrode 14 is larger than the area S1 of each overlapping region 131. The total area (which is four times the area S1) of the areas S1 of all the overlapping regions 131 in the second pixel electrode 14 is smaller than the area S4 of the remaining region 143. These configurations also contribute to reducing the coupling capacitance between the electrodes.

When the unit pixel 10 is viewed in plan view, the overlapping region between each first pixel electrode 13 and the second pixel electrode 14 does not necessarily have to exist. That is, in plan view, each first pixel electrode 13 and the second pixel electrode 14 may be in contact with each other or may be away from each other. In other words, in plan view, the first pixel electrode 13 and the second pixel electrode 14 do not necessarily have to overlap each other, and the area of the overlapping area may be zero. Such a configuration is advantageous in further reducing the coupling capacitance between the electrodes.

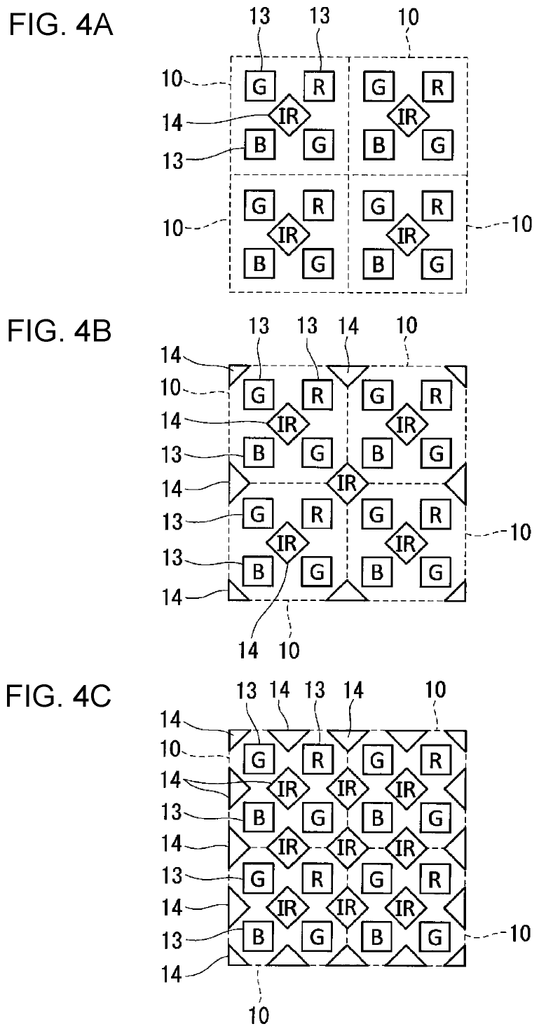

FIGS. 4A, 4B, and 4C illustrate another arrangement of the first pixel electrodes 13 and the second pixel electrodes 14. Letters “R”, “G”, “B”, and “IR” represent wavelength ranges (colors) of light for which the corresponding pixel electrodes collect charge. In each of the examples in FIGS. 4A, 4B, and 4C, no overlapping region exists. However, as described above with reference to FIGS. 3A and 3B, in each of the examples in FIGS. 4A, 4B, and 4C, an overlapping region may exist.

In the example illustrated in FIG. 4A, each unit pixel 10 includes four first pixel electrodes 13 and one second pixel electrode 14. The second pixel electrode 14 is surrounded by the four first pixel electrodes 13. The directions of diagonals of the second pixel electrode 14 are tilted 45 degrees with respect to the directions of diagonals of the first pixel electrodes 13. According to this configuration, it is possible to ensure a more sufficient area for the second pixel electrode 14 while reducing the coupling capacitance, which is advantageous in improving the sensitivity of the second pixels 10b (see FIG. 2A). According to the examples illustrated in FIGS. 3A and 4A, although the resolution of the second pixel array 104 is one-fourth the resolution of the first pixel array 102, the second pixel 10b has a large light-receiving area, and thus sufficient sensitivity is ensured.

In the example illustrated in FIG. 4B, an additional second pixel electrode 14 is provided at an intersection of four adjacent unit pixels 10. The ratio of the number of second pixel electrodes 14 to the number of first pixel electrodes 13 is 1 to 2. According to the example illustrated in FIG. 4B, the resolution of the second pixel array 104 is one-half of the resolution of the first pixel array 102.

In the example illustrated in FIG. 4C, an additional second pixel electrode 14 is provided on a boundary line of two adjacent unit pixels 10, in addition to the example illustrated in FIG. 4B. The orientation of the second pixel electrodes 14 is tilted 45 degrees with respect to the orientation of the first pixel electrodes 13. The ratio of the number of second pixel electrodes 14 to the number of first pixel electrodes 13 is 1 to 1. According to the example illustrated in FIG. 4B, the resolution of the second pixel array 104 is equal to the resolution of the first pixel array 102.

In the present embodiment, four first pixel electrodes 13 are provided in the same layer. However, this structure is not essential, and the first pixel electrode 13r, the first pixel electrodes 13g, and the first pixel electrode 13b may be provided in layers that are different from each other.

Next, the first shield electrode 23 and the second shield electrode 24 will be described in detail.

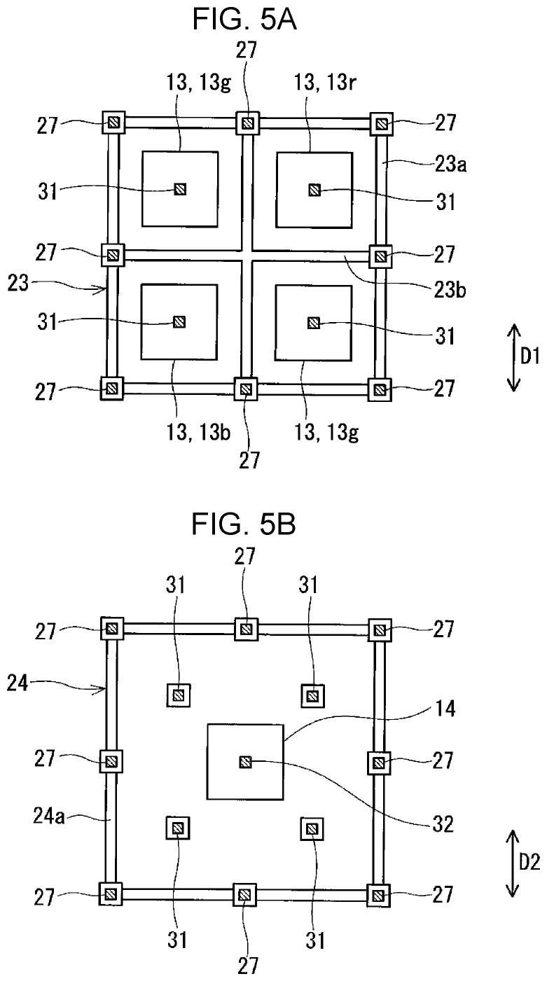

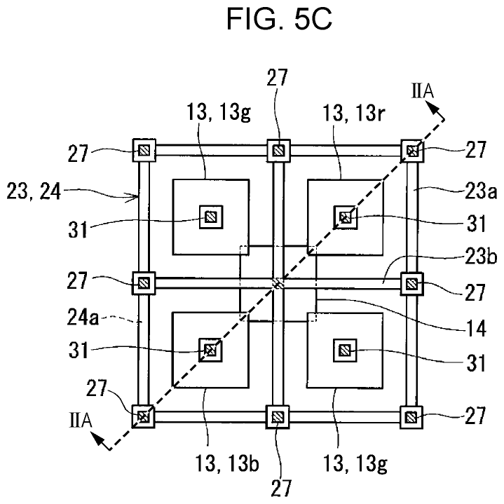

FIG. 5A is a plan view of the first pixel electrodes 13 and the first shield electrode 23. FIG. 5B is a plan view of the second pixel electrode 14 and the second shield electrode 24. FIG. 5C is a plan view of the first pixel electrodes 13, the first shield electrode 23, the second pixel electrode 14, and the second shield electrode 24. When the imaging device 100 is viewed in plan view, the first pixel electrodes 13, the first shield electrode 23, the second pixel electrode 14, and the second shield electrode 24 have a positional relationship illustrated in FIG. 5C.

The first shield electrode 23 has a frame shape that surrounds the first pixel electrodes 13. The charge collection efficiency improves in all directions around each first pixel electrode 13. The second shield electrode 24 also has a frame shape that surrounds the second pixel electrode 14. The charge collection efficiency improves in all directions around the second pixel electrode 14. An improvement of the charge collection efficiency leads to an improvement of the sensitivity.

As illustrated in FIG. 5A, the first shield electrode 23 includes an outer periphery portion 23a and a section portion 23b. The outer periphery portion 23a is a portion that surrounds four first pixel electrodes 13 that belong to each unit pixel 10. The outer periphery portion 23a has a frame shape. The section portion 23b is a portion that sections the region surrounded by the outer periphery portion 23a into four regions so that each first pixel electrode 13 is individually surrounded by the first shield electrode 23. The areas of the four regions are equal to each other. The section portion 23b has a cross shape. The section portion 23b is integrally formed with the outer periphery portion 23a, and the section portion 23b and the outer periphery portion 23a are electrically continuous with each other. The section portion 23b of the first shield electrode 23 does not overlap the second shield electrode 24.

As illustrated in FIG. 5B, the second shield electrode 24 includes an outer periphery portion 24a. The outer periphery portion 24a has a frame shape. In the example illustrated in FIG. 5B, the second shield electrode 24 does not have a portion corresponding to the section portion 23b of the first shield electrode 23. The design of the second shield electrode 24 is different from the design of the first shield electrode 23. The outer periphery portion 24a of the second shield electrode 24 has the same design as the design of the outer periphery portion 23a of the first shield electrode 23. This increases overlapping between the first shield electrode 23 and the second shield electrode 24, thus making it possible to sufficiently reduce a shield resistance.

FIG. 5C is an overlay of FIGS. 5A and 5B. In a stacking direction of the first pixel array 102 and the second pixel array 104, the outer periphery portion 23a of the first shield electrode 23 overlaps the second shield electrode 24. The first shield electrode 23 includes, as its outer periphery portion 23a thereof, linear portions that extend in first directions D1 illustrated in FIG. 5A. The second shield electrode 24 includes, as its outer periphery portion 24a thereof, linear portions that extend in second directions D2 illustrated in FIG. 5B. The first directions D1 and the second directions D2 are parallel to each other. The first directions D1 and the second directions D2 are, for example, longitudinal directions in the array direction of the unit pixels 10. In plan view, the linear portions of the first shield electrode 23 and the linear portions of the second shield electrode 24 overlap each other. The at least one plug 27 includes plugs 27 provided along the linear portions of the first shield electrode 23 and the linear portions of the second shield electrode 24. According to this configuration, it is possible to more sufficiently reduce the shield resistance.

According to the example illustrated in FIGS. 5A to 5C, in plan view, the second shield electrode 24 overlaps the first shield electrode 23 at 360 degrees around the second pixel electrode 14. Thus, the above-described advantages are obtained more sufficiently.

In the example illustrated in FIGS. 5A to 5C, the smallest distance between the first shield electrode 23 and the first pixel electrodes 13 differs from the smallest distance between the second shield electrode 24 and the second pixel electrode 14. The smallest distance between the first shield electrode 23 and the first pixel electrodes 13 is smaller than the smallest distance between the second shield electrode 24 and the second pixel electrode 14. Specifically, the smallest distance between the first shield electrode 23 and the first pixel electrodes 13 is the smallest distance between the outer periphery portion 23a of the first shield electrode 23 and the first pixel electrodes 13 or the smallest distance between the section portion 23b of the first shield electrode 23 and the first pixel electrodes 13. It is possible to sufficiently improve the sensitivity of the first pixels 10a (FIG. 2A) by arranging the first pixel electrodes 13 and the first shield electrode 23 sufficiently close to each other. Also, ensuring a sufficient distance between the second pixel electrode 14 and the second shield electrode 24 makes it possible to improve the charge collection efficiency over a wider range.

In plan view, an area M1 of the smallest region surrounded by the first shield electrode 23 differs from an area M2 of the smallest region surrounded by the second shield electrode 24. The former area M1 is smaller than the latter area M2. The first shield electrode 23 and the second shield electrode 24 have designs that suit the first pixel electrode 13 the second pixel electrode 14, respectively. According to the example illustrated in FIGS. 5A to 5C, the ratio (M1/M2) of the area M1 to the area M2 is about 1 to 4.

The cross section illustrated in FIG. 2A may be a cross section taken along a straight line IIA-IIA illustrated in FIG. 5C. In the example illustrated in FIGS. 5A to 5C, the first shield electrode 23 is located at an upper layer, and the second shield electrode 24 is located at a lower layer. When the position of the first pixel array 102 and the position of the second pixel array 104 are interchanged, the position of the first shield electrode 23 and the position of the second shield electrode 24 are also interchanged.

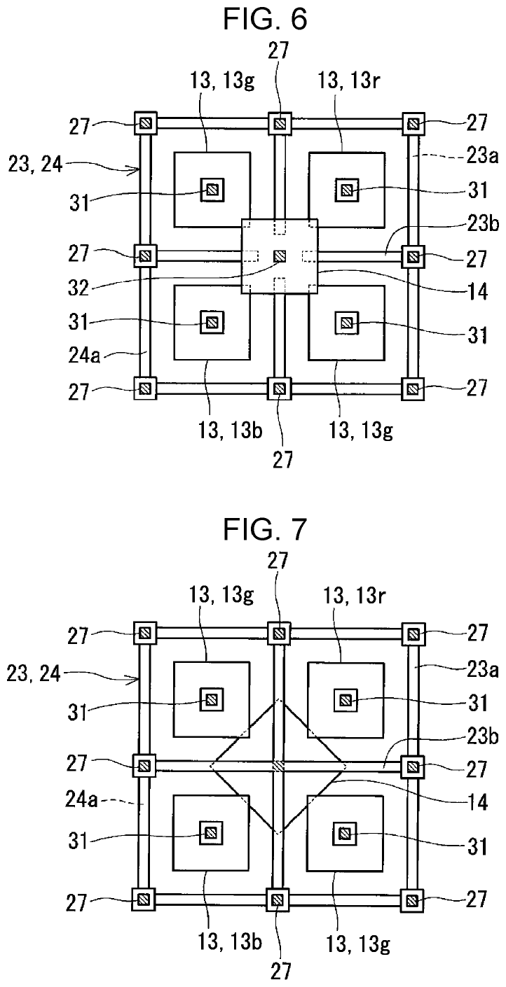

FIG. 6 is a plan view of the first pixel electrodes 13, the first shield electrode 23, the second pixel electrode 14, and the second shield electrode 24 when the second pixel array 104 is located at an upper layer, and the first pixel array 102 is located at a low layer. The first pixel array 102 at the lower layer has high resolution, and the second pixel array 104 at the upper layer has low resolution. The second plug 32 extends from the center region of the second pixel electrode 14 to the semiconductor substrate 1, and the section portion 23b of the first shield electrode 23 is provided avoiding the second plug 32.

FIG. 7 illustrates a modification of the example described above with reference to FIGS. 5A to 5C. In the modification illustrated in FIG. 7, the directions of the diagonals of the second pixel electrode 14 are tilted 45 degrees with respect to the directions of the diagonals of the first pixel electrodes 13. This arrangement is the same as the arrangement described above with reference to FIG. 4A. According to the modification illustrated in FIG. 7, it is possible to increase the area of the second pixel electrode 14, while reducing overlapping between the first pixel electrodes 13 and the second pixel electrode 14.

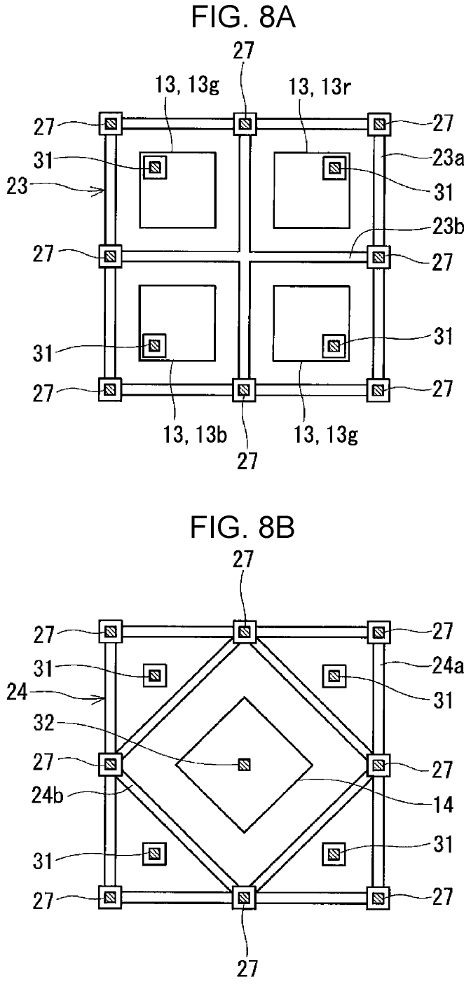

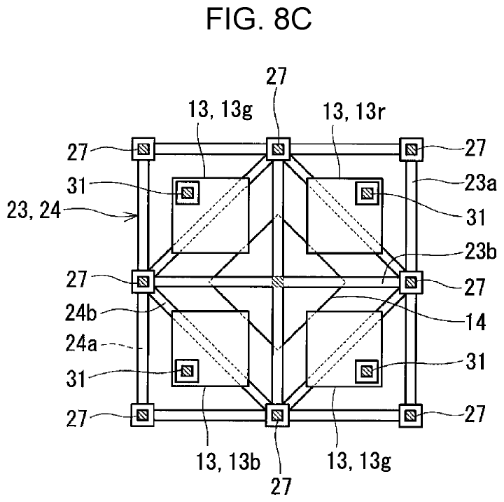

FIGS. 8A to 8C illustrate another modification. FIG. 8A is a plan view of the first pixel electrodes 13 and the first shield electrode 23. FIG. 8B is a plan view of the second pixel electrode 14 and the second shield electrode 24. FIG. 8C is a plan view of the first pixel electrodes 13, the first shield electrode 23, the second pixel electrode 14, and the second shield electrode 24.

As illustrated in FIG. 8A, the design of the first shield electrode 23 is the same as the design described above with reference to FIG. 5A. However, the positions of the first plugs 31 are moved from the center regions of the corresponding first pixel electrodes 13 to outer periphery regions thereof.

As illustrated in FIG. 8B, the second shield electrode 24 includes an outer periphery portion 24a and a section portion 24b. The outer periphery portion 24a is a portion having a frame shape. The section portion 24b is a portion that sections the region surrounded by the outer periphery portion 24a into a plurality of regions. More specifically, the section portion 24b has a rectangular frame shape and connects midpoints of four sides that constitute the outer periphery portion 24a. The section portion 24b is integrally formed with the outer periphery portion 24a, and the section portion 24b and the outer periphery portion 24a are electrically continuous with each other.

FIG. 8C is an overlay of FIGS. 8A and 8B. In plan view, the outer periphery portion 23a of the first shield electrode 23 overlaps the outer periphery portion 24a of the second shield electrode 24. The outer periphery portion 23a has the same design as that of the outer periphery portion 24a. The section portion 23b of the first shield electrode 23 does not overlap the second shield electrode 24. The section portion 24b of the second shield electrode 24 does not overlap the first shield electrode 23. In other words, in plan view, the first shield electrode 23 and the second shield electrode 24 have portions where they do not overlap each other. The first plugs 31 are provided at positions that do not overlap the section portion 24b of the second shield electrode 24. According to such a configuration, it is possible to provide shield electrodes that are suitable for the first pixel electrodes 13 and the second pixel electrode 14.

The first plugs 31 are located in regions that are different from the region included in the regions sectioned by the section portion 24b and in which the second pixel electrode 14 is provided. In the modification in FIG. 8C, the section portion 24b sections the region surrounded by the outer periphery portion 24a into one rectangular region and four triangular regions. The second pixel electrode 14 is provided in the rectangular region. The first plugs 31 are provided in the four triangular regions, respectively.

The first plugs 31 extend from the first pixel electrodes 13 to the semiconductor substrate 1. The second photoelectric conversion layer 122 requires vias for passing the first plugs 31 therethrough. When the vias are formed by processing, such as etching, damage caused by the etching in lateral directions remains in the photoelectric conversion layers. The damage that remains in the photoelectric conversion layers becomes a cause of leakage current. However, according to the example illustrated in FIG. 8C, the first plugs 31 are surrounded by the second shield electrode 24 at the same level as that of the second pixel electrode 14. That is, etched portions are surrounded by the second shield electrode 24. Owing to the potential gradient caused by the second shield electrode 24, the etched portions are separated from the second pixel electrode 14, and thus noise in the second pixel array 104 can be suppressed or reduced. The examples described above with reference to FIGS. 8A to 8C are particularly effective when a low-resolution pixel array is located at a lower layer, and a high-resolution pixel array is located at an upper layer.

According to this modification, shielding between the first plugs 31 and the second pixel electrode 14 is reliably achieved, thus making it possible to further reduce coupling between the first plugs 31 and the second pixel electrode 14. As a result, a further improvement of the sensitivity can be expected.

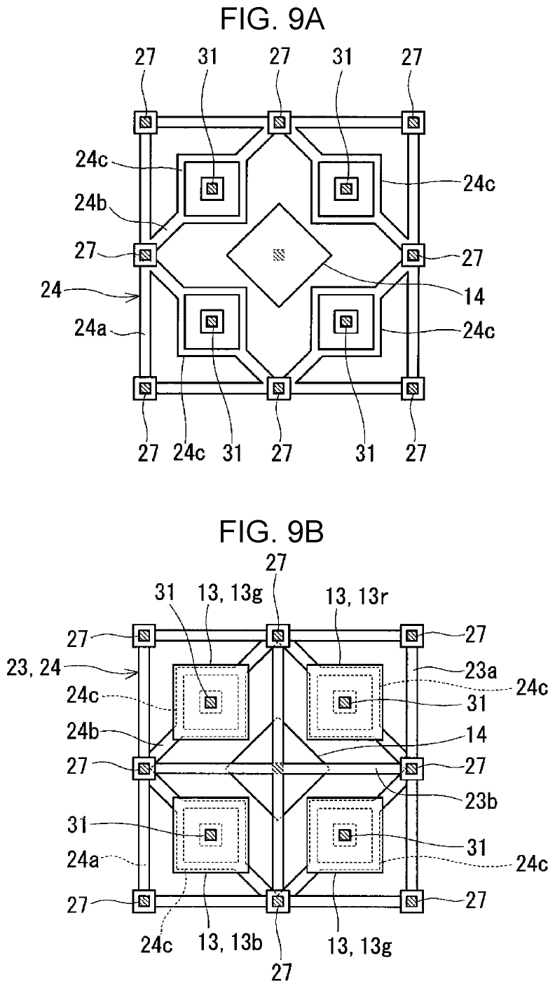

FIG. 9A is a plan view of the second pixel electrode 14 and the second shield electrode 24 in a further modification. The second shield electrode 24 includes the outer periphery portion 24a, the section portion 24b, and a plurality of small section portions 24c. The outer periphery portion 24a and the section portion 24b are the substantially the same as those described above with reference to FIG. 8B. Each small section portion 24c has a rectangular frame shape. The small section portions 24c are provided at respective four linear portions constituting the section portion 24b and surround the respective first plugs 31. The outer periphery portion 24a, the section portion 24b, and the small section portions 24c are integrally formed and are electrically continuous with each other.

FIG. 9B is an overlay of FIGS. 5A and 9A. In plan view, the outer periphery portion 23a of the first shield electrode 23 overlaps the outer periphery portion 24a of the second shield electrode 24. The outer periphery portion 23a has the same design as the design of the outer periphery portion 24a. The section portion 23b of the first shield electrode 23 does not overlap the second shield electrode 24. The section portion 24b of the second shield electrode 24 does not overlap the first shield electrode 23. In other words, in plan view, the first shield electrode 23 and the second shield electrode 24 have portions where they do not overlap each other.

The small section portions 24c of the second shield electrode 24 surround the corresponding first plugs 31 and also overlap the first pixel electrodes 13. In plan view, the outer shapes of the small section portions 24c may fit inside the outer shape of the first shield electrode 23 or may match the outer shape of the first shield electrode 23. At least part of the outer shape of each small section portion 24c may be located outside the outer shape of the first shield electrode 23, unless the small section portion 24c contacts the second pixel electrode 14.

This modification provides substantially the same advantages as those described above with reference to FIGS. 8A to 8C. Since shielding between the first plugs 31 and the second pixel electrode 14 is more reliably achieved, coupling between the first plugs 31 and the second pixel electrode 14 can be further reduced. As a result, a further improvement of the sensitivity can be expected.

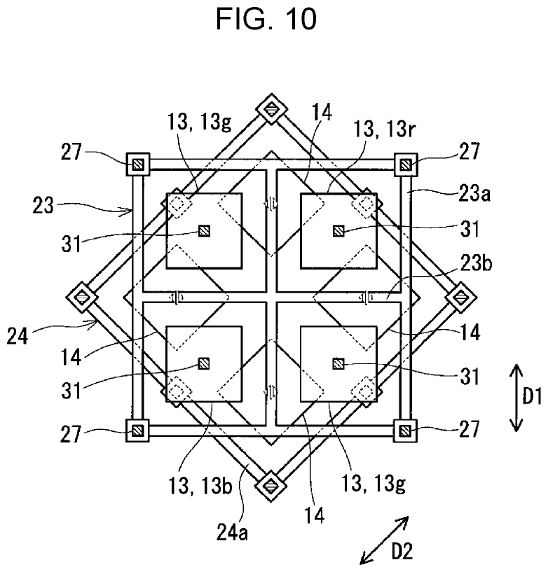

FIG. 10 is a plan view of the first pixel electrodes 13, the first shield electrode 23, the second pixel electrodes 14, and the second shield electrode 24 in yet another modification. In the modification illustrated in FIG. 10, the ratio of the number of second pixel electrodes 14 to the number of first pixel electrodes 13 is 1 to 1. The outer periphery portion 24a of the second shield electrode 24 surrounds four second pixel electrodes 14.

The designs of the first shield electrode 23 and the second shield electrode 24 are substantially the same as those described above with reference to FIGS. 5A and 5B. In addition, according to this modification, the directions of diagonals of the outer periphery portion 24a of the second shield electrode 24 are tilted 45 degrees with respect to the directions of diagonals of the outer periphery portion 23a of the first shield electrode 23. When the outer periphery portion 24a of the second shield electrode 24 is rotated 45 degrees, the outer periphery portion 24a matches the outer periphery portion 23a of the first shield electrode 23. The first shield electrode 23 includes, as its outer periphery portion 23a, linear portions that extend in first directions D1. The second shield electrode 24 includes, as its outer periphery portion 24a, linear portions that extend in second directions D2. The first directions D1 and the second directions D2 cross each other. The first directions D1 are tilted 45 degrees with respect to the second directions D2. Overlapping between the first shield electrode 23 and the second shield electrode 24 is minimized. The configuration illustrated in FIG. 10 is useful when different bias voltages are respectively applied to the first shield electrode 23 and the second shield electrode 24.

In the modification illustrated in FIG. 10, the first shield electrode 23 may be electrically insulated from the second shield electrode 24. A voltage to be applied to the first shield electrode 23 may be different from a voltage to be applied to the second shield electrode 24. Characteristics of the first photoelectric conversion layer 121 differ from characteristics of the second photoelectric conversion layer 122. Thus, according to this modification, it is possible to apply a voltage suitable for the second photoelectric conversion layer 122 to the second shield electrode 24, while applying a voltage suitable for the first photoelectric conversion layer 121 to the first shield electrode 23. As a result, a further improvement of the charge collection efficiency can be expected.

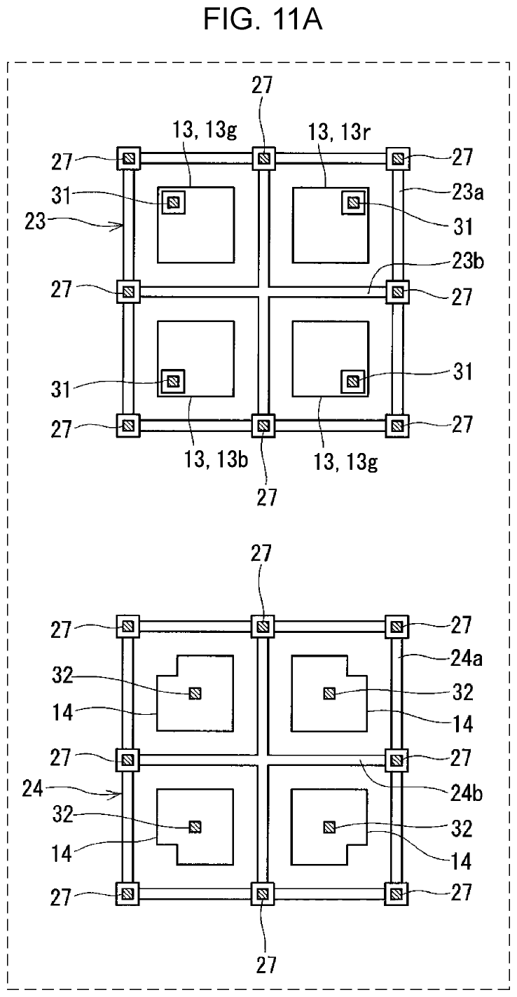

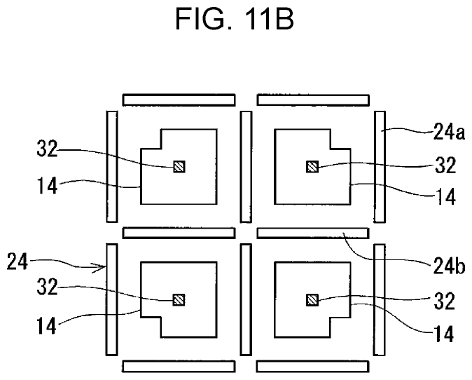

FIG. 11A includes plan views each illustrating the first pixel electrodes 13, the first shield electrode 23, the second pixel electrodes 14, and the second shield electrode 24 in still another modification. The upper view in FIG. 11A illustrates a set of the first pixel electrodes 13 and the first shield electrode 23. The lower view in FIG. 11A illustrates a set of the second pixel electrodes 14 and the second shield electrode 24. The structures illustrated in the upper and lower parts are stacked one on another. In the modification illustrated in FIG. 11A, the ratio of the number of second pixel electrode 14 to the number of first pixel electrodes 13 is 1 to 1. The outer periphery portion 24a of the second shield electrode 24 surrounds four second pixel electrodes 14.

In the modification illustrated in FIG. 11A, the first pixel electrodes 13 and the second pixel electrodes 14 generally match each other in plan view. The size of each second pixel electrode 14 generally matches the size of each first pixel electrode 13, except that the second pixel electrode 14 has a notch for passing the first plug 31. That is, an advantage provided by the first shield electrode 23 and the second shield electrode 24 is independent from an advantage provided by the offsetting of the first pixel electrodes 13 and the second pixel electrodes 14. Naturally, the combination of both the structures synergistically improves the sensitivity.

In the modification illustrated in FIG. 11A, the section portion 24b of the second shield electrode 24 has a cross shape. That is, the first shield electrode 23 and the second shield electrode 24 have substantially the same designs. Thus, it is possible to maximize the overlapping between the first shield electrode 23 and the second shield electrode 24.

Also, it is not essential that the second shield electrode 24 have a frame shape. For example, as illustrated in FIG. 11B, the outer periphery portion 24a may be constituted by linear portions that are separated from one another. The section portion 24b may also be constituted by linear portions that are separated from one another. Voltage application to the individual portions can be achieved through plugs. These structures also apply to the first shield electrode 23.

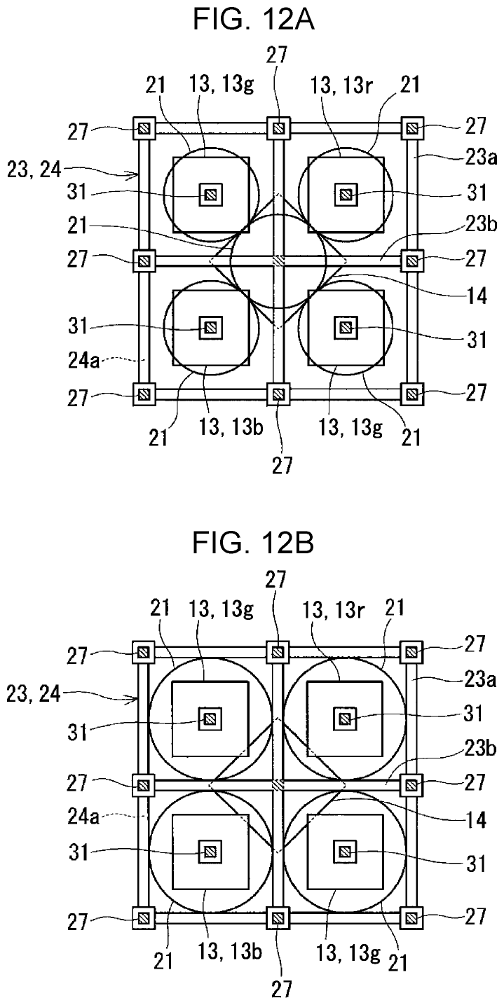

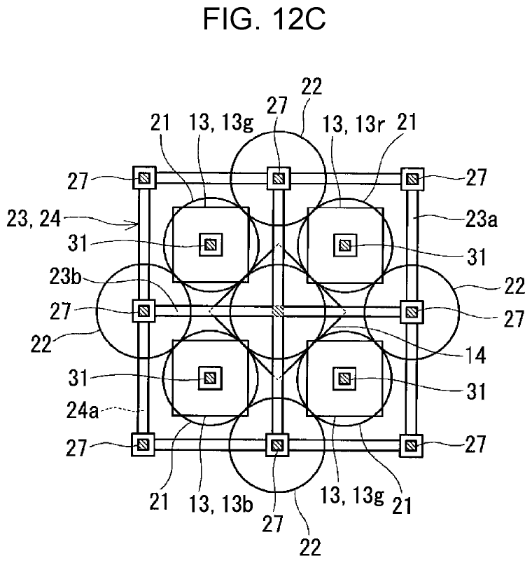

FIGS. 12A to 12C each illustrate an arrangement of the condensing lenses 21 in each unit pixel 10. The configuration of the first pixel electrodes 13, the first shield electrode 23, the second pixel electrode 14, and the second shield electrode 24 corresponds to the modification described above with reference to FIG. 7.

As illustrated in FIG. 12A, the condensing lenses 21 are provided at the upper side of the respective first pixel electrodes 13 and at an upper side of the second pixel electrode 14. Owing to functions of the condensing lenses 21, it is possible to improve the sensitivity of the first photoelectric conversion layer 121 and the sensitivity of the second photoelectric conversion layer 122.

As illustrated in FIG. 12B, the condensing lenses 21 may be provided only at the upper side of the respective first pixel electrodes 13. Since no condensing lens is provided at the upper side of the second pixel electrode 14, the sizes of the condensing lenses 21 provided at the upper side of the first pixel electrodes 13 can be increased. In this case, an incident angle increases, and the sensitivity also improves.

FIG. 12C illustrates an example in which dummy lenses 22 are provided in addition to the condensing lenses 21. The condensing lenses 21 are provided at the upper side of the respective first pixel electrodes 13 and second pixel electrode 14. No pixel electrodes are provided at a lower side of the dummy lenses 22. When large space exists between adjacent condensing lenses 21, it is difficult to fabricate condensing lenses 21 having a uniform shape. When the dummy lens 22 is provided between the adjacent condensing lenses 21, the uniformity of the shapes of the condensing lenses 21 improves.

Some other embodiments will be described below. Elements that are common to both the first embodiment and the other embodiments are denoted by the same reference numerals, and descriptions thereof may be omitted hereinafter. Descriptions of the embodiments can be applied to each other, as long as it is not technically contradictory. The embodiments may also be combined together, as long as such a combination is not technically contradictory.

### Second Embodiment

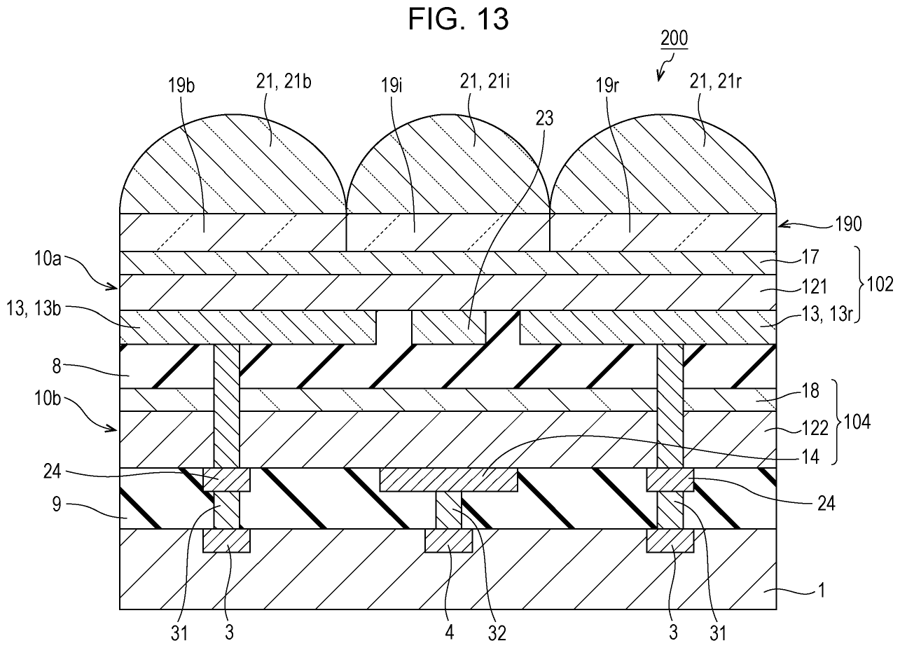

FIG. 13 illustrates a cross section of an imaging device 200 according to a second embodiment of the present disclosure. In the present embodiment, a color filter 190 corresponding to the second pixel electrode 14 is provided, and/or the condensing lenses 21 are provided at the upper side of the second pixel electrode 14. In these respects, the imaging device 200 differs from the imaging devices 100 and 110 described above.

The color filter 190 includes a first filter 19r, a third filter 19b, and a second filter 19i. The first filter 19r is a filter that transmits red light. The third filter 19b is a filter that transmits blue light. The second filter 19i is a filter that transmits near infrared light. A filter that transmits green light is arranged at a position (not illustrated) based on a Bayer arrangement.

In the present embodiment, the wavelength range of red light is defined as a first wavelength range. The wavelength range of near infrared light is defined as a second wavelength range. The wavelength range of blue light is defined as a third wavelength range different from the first wavelength range and the second wavelength range. Specifically, the center wavelength of the first wavelength range, the center wavelength of the second wavelength range, and center wavelength of the third wavelength range differ from one another.

The condensing lenses 21 include a first lens 21r, a second lens 21i, and a third lens 21b. The first lens 21r is arranged at the upper side of the first pixel electrode 13 that collects charge generated with red light. The third lens 21b is arranged at the upper side of the first pixel electrode 13 that collects charge generated with blue light. The second lens 21i is arranged at the upper side of the second pixel electrode 14 that collects charge generated with near infrared light. Another lens is also arranged at a position (not illustrated) at the upper side of the first pixel electrode 13 that collects charge generated with green light. The shapes of the lenses may be the same or may be different from one another. Materials of the lenses may be the same or may be different from one another.

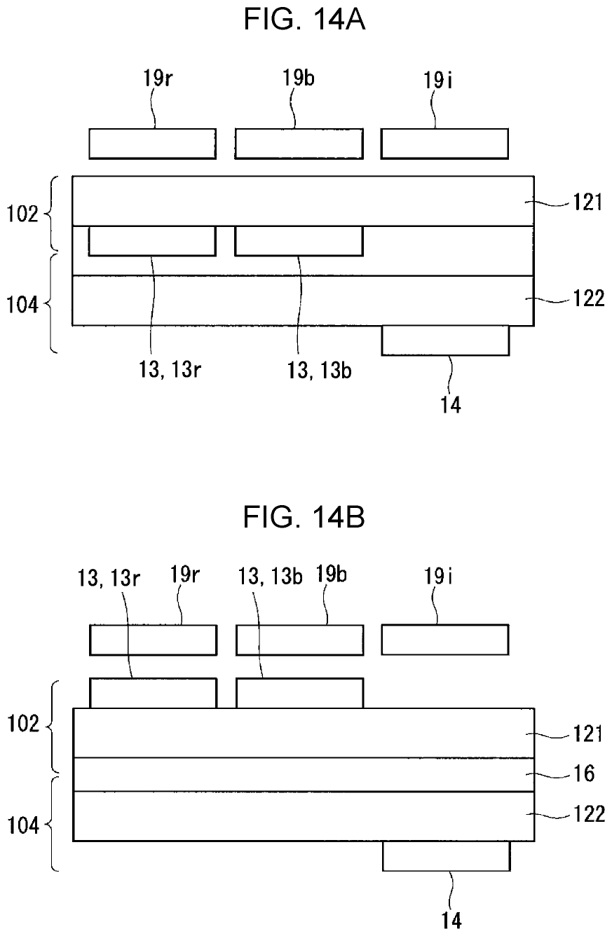

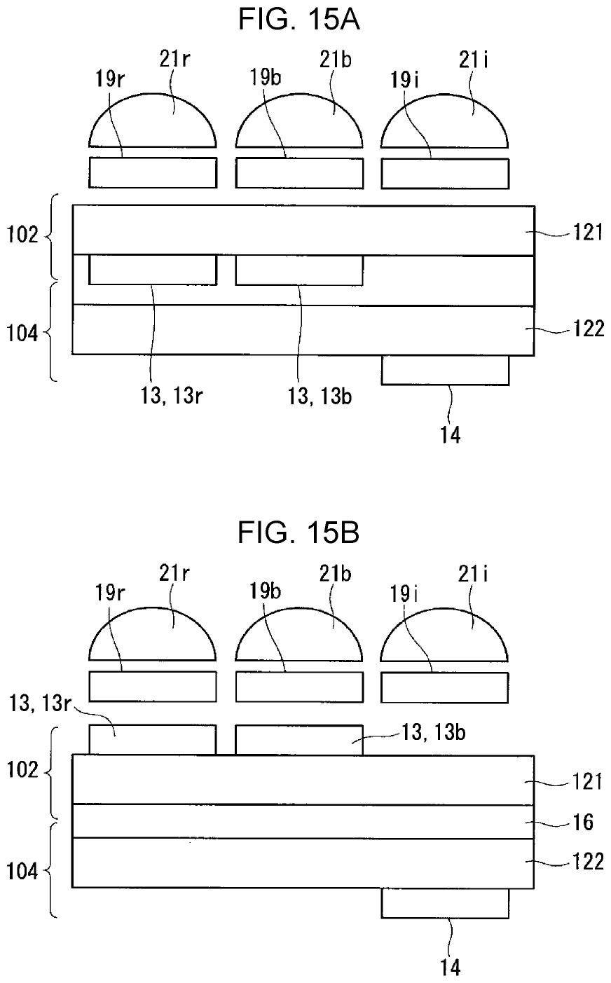

FIG. 14A schematically illustrates a positional relationship of the filters and the pixel electrodes. In plan view, the first filter 19r overlaps the first pixel electrode 13r, and the second filter 19i overlaps the second pixel electrode 14. According to this configuration, it is possible to efficiently read out light in specific wavelengths as signals, while reducing the coupling capacitance between each first pixel electrode 13 and the second pixel electrode 14. In addition, a uniform color filter array can be realized, yield improves, and color reproducibility also improves.

In plan view, the third filter 19b overlaps the first pixel electrode 13b that is different from the first pixel electrode 13r that the first filter 19r overlaps. According to this configuration, it is possible to efficiently read out light in three mutually different wavelength ranges as signals, while reducing the coupling capacitance between the pixel electrodes.

FIG. 14B is a schematic view illustrating another positional relationship of the filters and the pixel electrodes. The arrangement in the example illustrated in FIG. 14B is the same as the arrangement in the example described above with reference to FIG. 14A, except that the first pixel array 102 and the second pixel array 104 share a counter electrode 16.

FIG. 15A schematically illustrates a positional relationship of the lenses and the pixel electrodes. In plan view, an optical axis of the first lens 21r is located at the center region of the first pixel electrode 13r, and an optical axis of the second lens 21i is located at the center region of the second pixel electrode 14. Specifically, the optical axis of the first lens 21r passes through the center region of the first pixel electrode 13r and deviates from the center region of the second pixel electrode 14. The optical axis of the second lens 21i passes through the center region of the second pixel electrode 14 and also deviates from the center region of the first pixel electrode 13r. According to this configuration, it is possible to efficiently read out light in specific wavelengths as signals, while reducing the coupling capacitance between each first pixel electrode 13 and the second pixel electrode 14. A uniform lens array can be realized, yield improves, and also variations in incident angle characteristics are also suppressed or reduced.

In plan view, an optical axis of the third lens 21b is located at the center region of the first pixel electrode 13b that is different from the first pixel electrode 13r having the center region at which the optical axis of the first lens 21r is located. According to this configuration, it is possible to efficiently read out light in three mutually different wavelength ranges as signals, while reducing the coupling capacitance between the pixel electrodes.

FIG. 15B is a schematic view illustrating another positional relationship of the lenses and the pixel electrodes. The arrangement in the example illustrated in FIG. 15B is the same as the arrangement in the example described above with reference to FIG. 15A, except that the first pixel array 102 and the second pixel array 104 share the counter electrode 16. In FIG. 15B, the second filter 19i may be omitted.

According to the present embodiment, only one condensing lens 21 is provided for one pixel electrode. This is advantageous in reducing the pixel pitch and makes it possible to realize a higher-definition imaging device 200. A pixel electrode at an upper side of which no condensing lens 21 is provided may be provided. For example, when the first photoelectric conversion layer 121 is made of panchromatic material, and the second photoelectric conversion layer 122 is made of material having sensitivity to near infrared light, as described in the first embodiment, the condensing lenses 21 may be provided only at the upper side of the first pixel electrodes 13. No dedicated condensing lens is provided at the upper side of the second pixel electrode 14. According to this configuration, it is possible to form high-sensitivity and high-resolution images that suit human vision.

The first shield electrode 23 and/or the second shield electrode 24 may be omitted from the imaging device 200.

### Other Embodiments

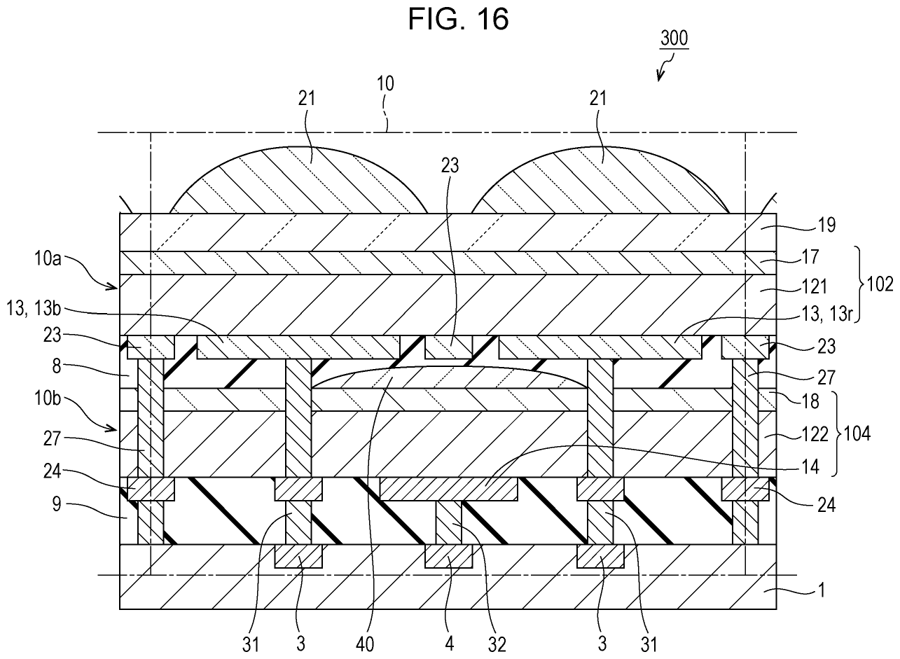

FIG. 16 is a sectional view of an imaging device 300 according to another embodiment. The imaging device 300 further includes condensing lenses 40. In the stacking direction, the condensing lenses 40 are arranged between the first pixel array 102 and the second pixel array 104 and at the upper side of the respective second pixel electrodes 14. According to the condensing lenses 40, larger amounts of light collected by the condensing lenses 21 can be guided to the second photoelectric conversion layer 122. As a result, the sensitivity of the second pixels 10b improves.

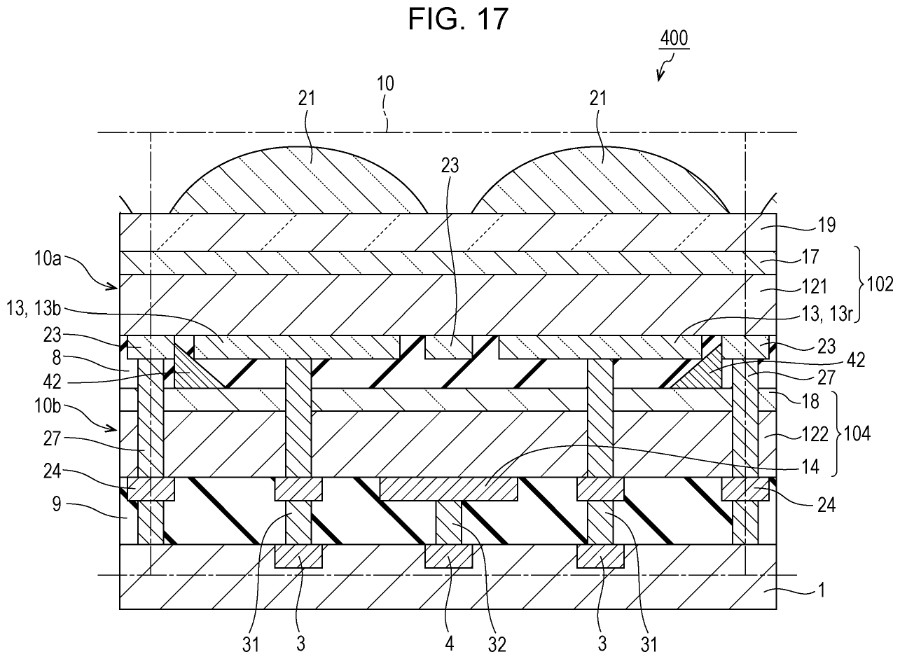

FIG. 17 is a sectional view of an imaging device 400 according to yet another embodiment. The imaging device 400 further includes waveguide structures 42. The waveguide structures 42 are arranged between the first pixel array 102 and the second pixel array 104 in the stacking direction. In plan view, the waveguide structures 42 are located around the respective second pixel electrodes 14. The waveguide structures 42 are configured so as to guide light in a particular direction by utilizing a refractive index difference between materials. For example, the waveguide structures 42 can be fabricated with a combination of silicon nitride and silicon dioxide. According to the waveguide structures 42, it is possible to guide larger amounts of light to the second photoelectric conversion layer 122. As a result, the sensitivity of the second pixels 10b improves.

The condensing lenses 40 described above with reference to FIG. 16 and the waveguide structures 42 described above with reference to FIG. 17 can also be employed in other embodiments, as appropriate.

### (Embodiment of Camera System)

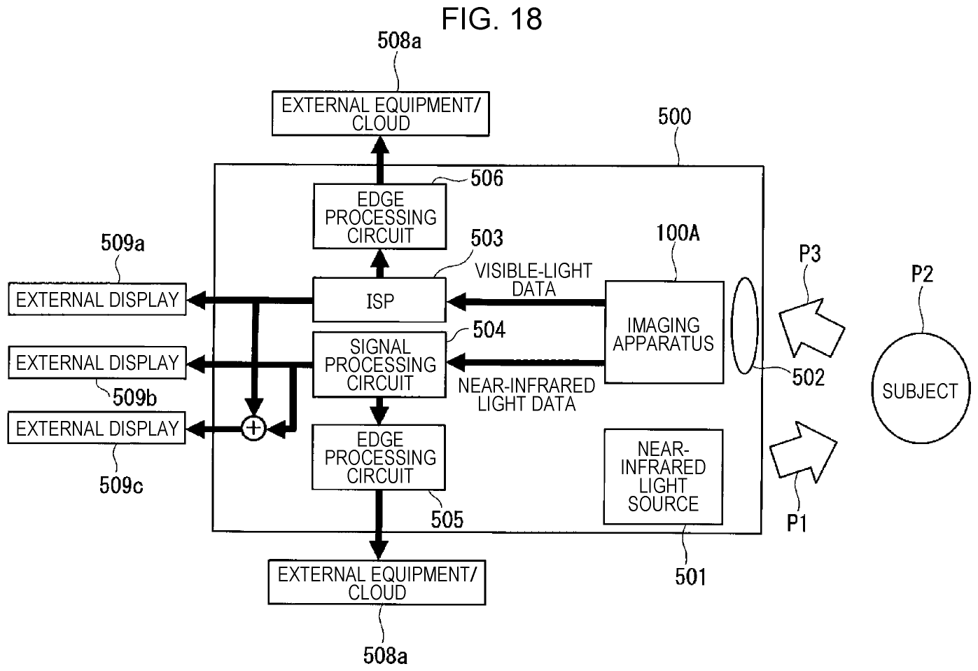

FIG. 18 illustrates a configuration of a camera system 500. The camera system 500 includes the imaging apparatus 100A, a near-infrared light source 501, a lens 502, an image signal processor (ISP) 503, a signal processing circuit 504, and edge processing circuits 505 and 506. The camera system 500 is configurated to process data based on light in two wavelength ranges, the data being obtained by the imaging apparatus 100A, and to output the resulting data.

Near infrared light P1 is emitted from the near-infrared light source 501 to a subject P2. The imaging apparatus 100A receives light P3 from the subject P2 via the lens 502. The imaging apparatus 100A outputs data based on visible light and data based on near infrared light through two channels. The ISP 503 processes the data based on visible light to thereby acquire a full-color image. The full-color image is sent to an external display 509a and is displayed thereon. The full-color image is also processed by the edge processing circuit 506, and then the resulting full-color image is transmitted to external equipment and/or a cloud 508a. The signal processing circuit 504 processes the data based on near infrared light to thereby acquire an image resulting from near infrared light. The signal processing circuit 504 may be configurated so as to calculate a distance to the subject P2 by using the data based on near infrared light. The image resulting from near infrared light is transmitted to an external display 509b and is displayed thereon. The image resulting from near infrared light is processed by the edge processing circuit 505, and then the resulting image is transmitted to the external equipment and/or the cloud 508a. The full-color image and the image resulting from near infrared light can be added to each other and be displayed on an external display 509c.

The technology disclosed herein is useful for imaging devices. The imaging devices can be applied to imaging apparatuses, optical sensors, and so on. Example of the imaging apparatuses include camera systems, such as digital still cameras, medical cameras, surveillance cameras, on-board cameras, digital single-lens reflex cameras, and digital mirrorless single-lens reflex cameras.

What is claimed is:

1. An imaging device comprising:
a first pixel array including a first photoelectric converter and first pixel electrodes connected to the first photoelectric converter; and
a second pixel array including a second photoelectric converter and second pixel electrodes connected to the second photoelectric converter, wherein
the first pixel array and the second pixel array are stacked one on another; and
in a plan view, an area of an overlapping region defined by overlapping between the first pixel electrodes and a corresponding second pixel electrode of the second pixel electrodes is smaller than an area of a remaining region obtained by excluding the overlapping region from the corresponding second pixel electrode.

2. The imaging device according to claim 1, further comprising:
a first filter that transmits light in a first wavelength range; and
a second filter that transmits light in a second wavelength range, wherein
a center wavelength of the first wavelength range differs from a center wavelength of the second wavelength range; and
in the plan view, the second filter overlaps the corresponding second pixel electrode and does not overlap the first pixel electrodes.

3. The imaging device according to claim 1, further comprising:
a first lens; and
a second lens, wherein,
in the plan view, an optical axis of the second lens is located at a center region of the corresponding second pixel electrode and deviates from a center region of each of the first pixel electrodes.

4. The imaging device according to claim 1,
wherein, in the plan view, the first pixel electrodes and the second pixel electrodes do not overlap each other, and the area of the overlapping region is zero.

5. The imaging device according to claim 2, further comprising:
a third filter that transmits light in a third wavelength range different from the first wavelength range and the second wavelength range,
wherein, in the plan view, the third filter overlaps a first pixel electrode that is included in the first pixel electrodes and that does not overlap the first filter.

6. The imaging device according to claim 3, further comprising:
a third lens, wherein,
in the plan view, an optical axis of the third lens is located at a center region of a first pixel electrode that is included in the first pixel electrodes, and
the optical axis of the first lens is not located at the center region of the first pixel electrode.

7. The imaging device according to claim 6,
wherein an optical axis of the second lens deviates from a center region of each of the first pixel electrodes.

8. The imaging device according to claim 2, wherein
the first pixel array is arranged closer to a light-receiving surface of the imaging device than the second pixel array; and
a wavelength of the light in the second wavelength range is longer than a wavelength of the light in the first wavelength range.

9. The imaging device according to claim 2, wherein
the second pixel array is arranged closer to a light-receiving surface of the imaging device than the first pixel array; and
a wavelength of the light in the second wavelength range is longer than a wavelength of the light in the first wavelength range.

10. The imaging device according to claim 1,
wherein each of the first pixel electrodes includes indium tin oxide.

11. The imaging device according to claim 2,
wherein the first wavelength range includes a wavelength range of visible light.

12. The imaging device according to claim 2,
wherein the second wavelength range includes a wavelength range of near infrared light.

13. The imaging device according to claim 1, further comprising:
a substrate that supports the first pixel array and the second pixel array;
first plugs; and
second plugs, wherein
each of the first plugs connects a corresponding one of the first pixel electrodes and the substrate;
each of the second plugs connects a corresponding one of the second pixel electrodes and the substrate; and
in the plan view, each of the first plugs does not overlap the second pixel electrodes, and each of the second plugs does not overlap the first pixel electrodes.
